(19) United States
(12) Patent Application Publication
(10) Pub. No.: US 2016/0322781 A1
(43) Pub. Date: Nov. 3, 2016

(54) DISSIPATING HEAT FROM ELECTRONIC DEVICES

(71) Applicant: Corning Optical Communications Wireless Ltd, Airport City (IL)

(72) Inventors: Rami Anolik, Beit Arie (IL); Ami Hazani, Ra'anana (IL); Gavriel Magnezi, Petah Tikva (IL); Pinhas Yehuda Rosenfelder, Beit-Shemesh (IL)

(21) Appl. No.: 15/207,684

(22) Filed: Jul. 12, 2016

Related U.S. Application Data
(63) Continuation of application No. PCT/IL2015/050045, filed on Jan. 13, 2015.
(60) Provisional application No. 61/926,522, filed on Jan. 13, 2014.

(51) Int. Cl. H01S 5/024; H05K 7/20

(52) U.S. Cl. CPC H01S 5/02469; H05K 7/209

(57) ABSTRACT

An electronic apparatus includes first and second electronic devices, and first and second heat sinks for dissipating heat, wherein there is each of electrical conductivity between the first electronic device and the first heat sink, thermal conductivity between the first electronic device and the first heat sink, electrical conductivity between the second electronic device and the second heat sink, and thermal conductivity between the second electronic device and the second heat sink, wherein electrical conductivity is provided between the first and second heat sinks, and wherein thermal resistance is provided between the first and second heat sinks, so that the second heat sink remains cooler than the first heat, such as for protecting the second electrical device from the heat generated by the first electronic device.

### PRIORITY APPLICATION

This application is a continuation of International Application No. PCT/IL15/050045 filed on Jan. 13, 2015, which claims the benefit of priority to U.S. Provisional Application Ser. No. 61/926,522 filed on Jan. 13, 2014, both applications being incorporated herein by reference.

### BACKGROUND

This disclosure relates generally to dissipating heat from an electronic apparatus and, more particularly, to dissipating heat from a power amplifier and a laser diode, wherein the laser diode may be used for transmitting optical signals through an optical fiber cable.

An electronic device typically generates heat while operating. The temperature of the electronic device depends on both the heat generated in the device (e.g., measured in Watts (“W”)) and the thermal resistance between the electronic device and the surrounding ambient environment (e.g., measured in degrees per Watt (“C/W”)). It is known to reduce the temperature of electronic devices by connecting them to a heat sink that provides low thermal resistance between the devices and the ambient environment. A heat sink with a large dissipation area may be required for achieving sufficient heat dissipation. It is common for the enclosure (e.g., chassis) of an electronic apparatus to be used as a heat sink, wherein electronic devices of the apparatus are connected to the enclosure for dissipating their heat. It is also known for the enclosure to be used as a common ground plane that provides a low electrical impedance to the “ground” for the electronic devices that are connected to it.

No admission is made that any reference cited herein constitutes prior art. Applicant expressly reserves the right to challenge the accuracy and pertinency of any cited documents.

### SUMMARY

An embodiment of this disclosure relates to an electronic apparatus including first and second electronic devices respectively connected to first and second heat sinks for dissipating heat, wherein there is each of: electrical conductivity between the first electronic device and the first heat sink, thermal conductivity between the first electronic device and the first heat sink, electrical conductivity between the second electronic device and the second heat sink, and thermal conductivity between the second electronic device and the second heat sink.

In one aspect of this disclosure, there may be at least one feature (e.g., gap(s) and conductive electrical bridge(s)) between the first and second heat sinks, wherein the at least one feature is configured for simultaneously providing electrical conductivity between the first and second heat sinks, thermal conductivity between the first and second heat sinks, and thermal resistance between the first and second heat sinks, wherein the thermal resistance between the first and second heat sinks seeks to maintain the second heat sink at a lower temperature than the first heat sink, such as for protecting the second electrical device from the heat generated by the first electronic device.

The at least one feature between the first and second heat sinks may comprise an electrical bridge extending across a gap between the heat sinks. The first electronic device may be a high-powered amplifier, and the second electronic device may be a temperature-sensitive laser diode.

In another aspect of this disclosure, the thermal conductivity between the first and second heat sinks may be less than (i) the thermal conductivity between the first electronic device and the first heat sink and/or (ii) the thermal conductivity between the second electronic device and the second heat sink.

One aspect of this disclosure is the provision of a method of at least partially making an electronic apparatus. The method may include restricting thermal conductivity between the first and second heat sinks without eliminating electrical conductivity between the first and second heat sinks. For example, one or more gaps between the heat sinks may restrict the thermal conductivity, whereas the one or more electrical bridges between the heat sinks may provide a predetermined amount of electrical conductivity. In this regard, one aspect of this disclosure seeks to enhance the coexistence of relatively lower power, temperature-sensitive electronic devices and relatively higher power electronic devices in the same electronic apparatus (e.g., in the same enclosure), such as by simultaneously seeking to avoid overheating of the temperature-sensitive devices and providing good electrical continuity in the ground plane of the electronic apparatus, wherein the ground plane may include the electrical bridge(s) and the heat sinks.

Additional features and advantages will be set forth in the detailed description which follows, and in part will be readily apparent to those skilled in the art from the description or recognized by practicing the embodiments as described in the written description and claims hereof, as well as the appended drawings.

It is to be understood that both the foregoing general description and the following detailed description are merely exemplary, and are intended to provide an overview or framework to understand the nature and character of the claims.

The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 schematically illustrates a relatively high-power electronic device and a relatively low-power, temperature-sensitive electronic device, wherein these devices are respectively connected to large and small heat sinks that are connected to one another by an electrical bridge, in accordance with a first embodiment of this disclosure.

FIG. 2 schematically illustrates a prophetic thermal model of the assembly shown in FIG. 1, in accordance with the first embodiment.

FIG. 3 is a schematic, isolated, top plan view of a precursor to the large and small heat sinks of the first embodiment.

FIG. 4 is similar to FIG. 3, except that the precursor has been cut to form a gap and, thereby, define the large and small heat sinks of the first embodiment.

FIG. 5 is similar to FIG. 4, except for showing the electrical bridge connected between the heat sinks, in accordance with the first embodiment.

FIG. 6 is a cross-sectional view that schematically illustrates a relatively high-power electronic device and a laser diode respectively connected to large and small heat sinks that are connected to one another by electrical bridges, wherein the cross-section is taken substantially along line 6-6 of FIG. 7, in accordance with a second embodiment of this disclosure.

FIG. 7 is a schematic, top plan, substantially isolated view of the heat sinks of FIG. 6, in accordance with the second embodiment.

FIG. 8 schematically illustrates a comparative example, wherein a relatively high-power electronic device and a relatively low-power, temperature-sensitive electronic device are connected to the same heat sink.

FIG. 9 schematically illustrates a comparative prophetic thermal model of the assembly shown in FIG. 8.

### DETAILED DESCRIPTION

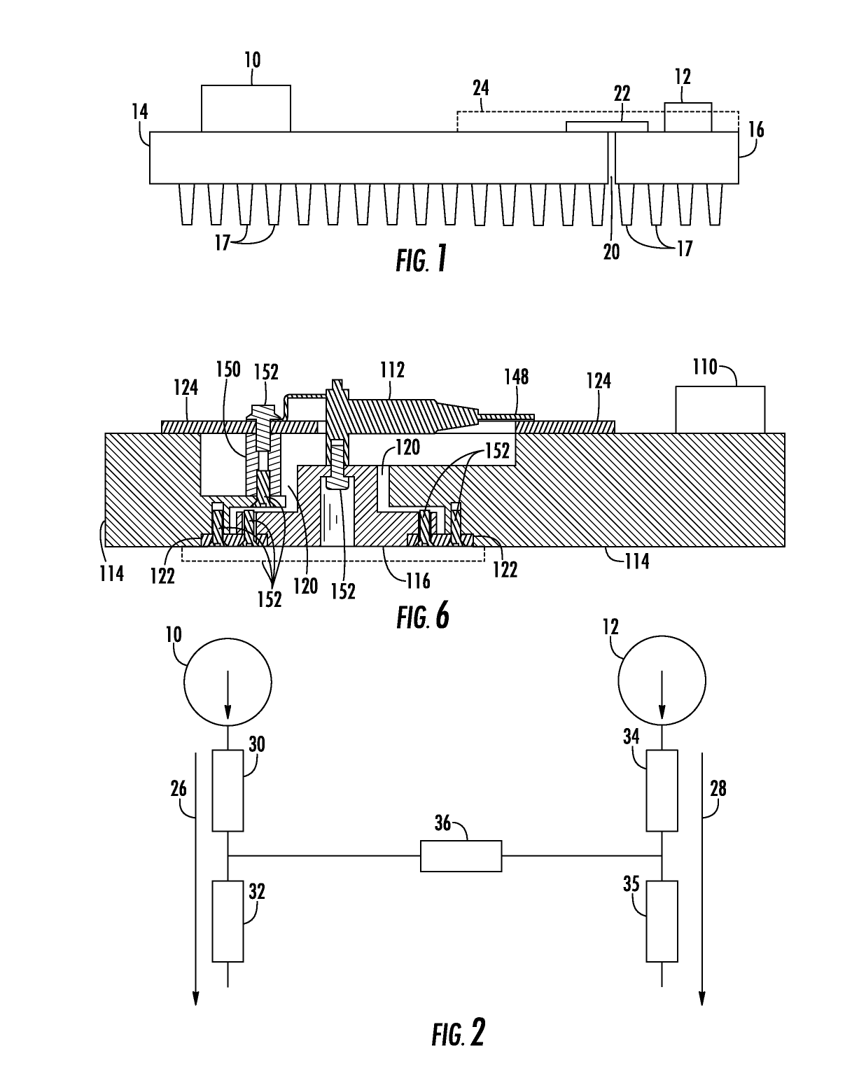

FIG. 1 schematically illustrates some of the features of an electronic apparatus of a first embodiment of this disclosure, wherein the electronic apparatus includes electronic devices 10, 12 that are respectively connected to heat sinks 14, 16. The heat sinks 14, 16 each may be plate-like or in any other suitable configuration. For example and not for the purpose of limiting the scope of this disclosure, a first of the electronic devices 10, 12 may be a relatively high-power electronic device such as a power amplifier 10; a second of the electronic devices 10, 12 may be a relatively low power, temperature-sensitive electronic device such as a laser diode 12; and as compared to one another, the heat sinks 14, 16 may be a relatively large, main heat sink 14 and a relatively small, secondary heat sink 16. Each heat sink 14, 16 may be made of metal or another suitable material so that it has good electrical and thermal conductance. Optionally, each heat sink 14, 16 may include fins 17 for increasing the heat transfer by convention between the heat sink and ambient fluid (e.g., air) that is in contact with the heat sink. The electronic apparatus of the first embodiment may include any suitable number of amplifiers 10, laser diodes 12, main heat sinks 14 and/or secondary heat sinks 16. The enclosure (e.g., chassis) of the electronic apparatus of the first embodiment may comprise, consist of, or consist essentially of the heat sinks 14, 16.

For each of the electronic devices 10, 12 and the heat sink 14, 16 to which it is respectively connected, the connecting is such that there is both electrical and thermal communication between the electronic device and the heat sink. For example, for each of the electronic devices 10, 12 and the heat sink 14, 16 to which it is respectively connected, the electronic device and the heat sink may be in direct contact (e.g., in opposing face-to-face contact) with one another, and they may be secured to one another with one or more fasteners such as, but not limited to, screws. As another example, for each of the electronic devices 10, 12 and the heat sink 14, 16 to which it is respectively connected, one or more interposing objects (not shown) having good electrical and thermal conductance may be positioned between the electronic device and the heat sink, so that the electrical and thermal communication between the electronic device and the heat sink is by way of the interposing object(s). For each of the electronic devices 10, 12 and the heat sink 14, 16 to which it is respectively connected, the connecting may be carried out in any suitable manner for providing, either directly or indirectly, sufficient electrical and thermal communication between the electronic device and the heat sink. For each of the electronic devices 10, 12 and the heat sink 14, 16 to which it is respectively connected, the heat sink is for at least indirectly receiving heat from the electronic device by way of conduction, and for dissipating the heat, such to the ambient environment by way of convection.

The heat sinks 14, 16 are at least partially, and preferably (e.g., optionally) substantially, thermally isolated from one another by way of at least one gap 20 defined between the heat sinks 14, 16. The gap(s) 20 between the heat sinks 14, 16 are configured for restricting thermal communication between the heat sinks. Air or any other suitable thermally insulating material may be positioned in the gap(s). The thermal isolation between the heat sinks 14, 16 may be referred to as being substantial, rather than being infinitely complete, because, for example and in some situations, there may be (e.g., a relatively small amount) of convective and radiant heat transfer across the gap 20. Additionally and in accordance with the first embodiment, at least one electrical bridge 22 is connected to the heat sinks 14, 16 and spans across the gap 20, wherein the electrical bridge may provide a relatively small amount of conductive thermal communication between the heat sinks. Typically the electronic apparatus of the first embodiment will be configured and will be operative such that the prominent thermal communication between bodies (e.g., electronic devices 10, 12, heat sinks 14, 16 and electrical bridges 22) that are in contact with one another will be in the form of conduction.

As examples, each electrical bridge 22 may be in the form of, or may include, an electrical conductor, or electrical conductors connected in series, wherein opposite ends of each electrical bridge may be respectively connected either directly or indirectly to the heat sinks 14, 16. For example, the electrical bridge 22 may be in the form of an electrical conductor such as, but not limited to, electrically conductive wire, an electrically conductive strip, an electrically conductive trace, an electrically conductive pad and/or any other suitable electrical connector. In accordance with the first embodiment and as will be discussed in greater detail below, the size and/or other characteristics of the electrical bridge 22 are selected so that the electrical bridge has very low thermal conductance and good electrical conductance. For example, the electrical bridge 22 may be configured so that it simultaneously provides both good electrical conductivity between the heat sinks 14, 16 and relatively low thermal conductivity between the heat sinks 14, 16. Stated differently for an additional example, the electrical bridge 22 may be configured so that it simultaneously provides both good electrical communication between the heat sinks 14, 16 and low thermal communication between the heat sinks. Stated another way for an additional example, the electrical bridge 22 may be configured so that simultaneously the heat sinks 14, 16 are both in good electrical communication with one another and substantially thermally isolated from one another.

As one specific example, the electric bridge 22 may be a conductive trace of a printed circuit board, as will be discussed in greater detail below, wherein the conductive trace/electric bridge 22 may be copper, and at least in theory the conductive trace/electric bridge may have a thickness of about 0.035 mm, or the conductive trace/electric bridge may have any other suitable thickness selected from the group consisting of the conventional thicknesses of conductive traces of circuit boards. As additional examples and at least in theory, the conductive trace/electric bridge may have a thickness of about 0.175 mm or less, may have a thickness of about 0.14 mm or less, may have a thickness of about 0.105 mm or less, may have a thickness of about 0.070 mm or less, or the thickness may range between any of the preceding values provided for the conductive trace/electric bridge.

Although other types of circuitry are within the scope of this disclosure, the electronic apparatus of the first embodiment includes radio frequency circuitry, wherein at least the laser diode 12 and the radio frequency circuitry are cooperatively configured so that the laser diode is for providing analog modulation of radio frequency signals over optical fiber. That is, an end of the laser diode 12 may be coupled to an end of an optical fiber cable (not shown in FIG. 1) for transmitting optical signals through the cable in response to electrical signals being supplied to the laser diode from a circuit board of the electronic apparatus of the first embodiment.

In accordance with the first embodiment, the ground plane of the electronic apparatus comprises the heat sinks 14, 16, wherein the main ground plane comprises the main heat sink 14. Also in accordance with the first embodiment, the at least one gap 20 and/or the at least one electrical bridge 22 are typically configured for providing both: (i) low resistance ground connectivity that seeks to provide for optimal performance of the radio frequency circuitry of the electronic apparatus, wherein there is very low electrical resistance between the body of the laser diode 12 and the main ground plane (e.g., the main heat sink 14); and (ii) high thermal resistance between the body of the laser diode and the main ground plane (e.g., the main heat sink 14). This high thermal resistances is provided since the heat that flows from the high power devices (e.g., the amplifier 10) of the electronic apparatus to the main ground plane (e.g., the main heat sink 14) may cause the main heat sink 14 to reach a temperature that may degrade the performance of, or may damage, temperature-sensitive electronic devices (e.g., the laser diode 12) of the electronic apparatus. Stated differently, one aspect of this disclosure is the provision of structure(s) (e.g., the gap 20 and the electrical bridge 22) that seek to prevent high power devices (e.g., the amplifier 10) from causing over heating of sensitive devices (e.g., the laser diode 12), while at the same time providing both adequate heat dissipation to the ambient environment and adequate electrical conductivity between parts of the ground plane (e.g., the heat sinks 14, 16). The subject structure(s) (e.g., the gap 20 and the electrical bridge 22) may be utilized in various situations where it is desirable to reduce the heat interaction/influence of two or more electronic devices (e.g., amplifier 10 and diode 12) by substantially isolating them from one another with respect to thermal conductivity, while at the same time maintaining a low electrical resistance between them. More specifically, the one or more electrical bridges 22 seek to provide very low electrical resistance between the body of the laser diode 12 and the main ground plane (e.g., the main heat sink 14).

In the first embodiment, the same metal structure which is used as the main heat sink 14 is also used for providing the common ground connectivity to the relevant devices of the electronic apparatus of the first embodiment, and the secondary heat sink 16 may be cut out of the main heat sink 14, or cut out of a precursor to the heat sinks, as will be discussed in greater detail below. The one or more electrical bridges 22 are typically configured for providing good ground connection between the laser diode 12 on the secondary heat sink 16 and the main ground plane (e.g., the main heat sink 14).

In one aspect of this disclosure, each of the one or more secondary heat sinks 16 may optionally be characterized as, or may be referred to as, an island heat sink 16, and each island heat sink may be is at least partially positioned in a hole defined in the main heat sink 14 of the electronic apparatus of the first embodiment. In one specific example, each island heat sink 16 may be circumscribed by a gap 20 that is circumscribed by the main heat sink 14. More generally, each island heat sink 16 may be at least partially circumscribed by a gap 20 that is at least partially circumscribed by the main heat sink 14. Other configurations are also within the scope of this disclosure, such that the secondary heat sinks 16 are not limited to island heat sinks. That is, the secondary heat sinks 16 (e.g., island heat sinks) may be referred to by any other suitable name. Similarly, the main heat sink 14 may be referred to by any other suitable name.

The relatively low power, temperature-sensitive devices (e.g., laser diode 12) that do not require a large heat sink may be connected to the secondary heat sinks 16. In contrast, the relatively higher power devices (e.g., amplifier 10) may be connected to the main heat sink 14. Ground plane continuity between the secondary heat sinks 16 and the main heat sink 14 may be provided by respective electrical bridges 22 that may be in the form of metal strips, conductive portions of printed circuit boards and/or other suitable features that are connected between the secondary heat sinks and the main heat sink in a way that provides adequate ground plane electrical connectivity. For example, it may be advantageous to use very thin metal films of printed circuit boards as the electrical bridges 22 because such very thin metal films have both relatively high electrical conductance and relatively high thermal resistance. More generally, the electrical bridges 22 may be any suitable thin metal strips, or other suitable features, with relatively high electrical conductance and relatively high thermal resistance.

Since the one or more electrical bridges 22 may optionally be parts of one or more printed circuit boards, in FIG. 1 such a printed circuit board 24 is schematically illustrated by dashed lines as including the electrical bridge 22. In the first embodiment, the laser diode 12 may be mounted to the circuit board 24, the amplifier 10 may be connected to the circuit board, and the radio frequency circuitry may be incorporated into the circuit board; and at least these features are cooperatively configured for allowing the laser diode to transmit optical signals through an optical fiber cable, as will be discussed in greater detail below. The laser diode 12 may be positioned in a through-hole (e.g., cut-out) in the circuit board 24.

Those of ordinary skill in the art will understand how to make a circuit board so that it includes one or more units (e.g., layers) that are secured in a stacked arrangement by laminating and/or other suitable fastening techniques, wherein each unit typically includes a slab-shaped, non-conductive substrate having opposite top and bottom major sides, and one or more conductors (e.g., conductive traces and/or conductive pads) mounted to one or both of the major sides. The layers or units of the circuit board 24 provide room for “running area” for the conductive traces connecting between the components of the circuit board. The circuit board 24 may include any suitable number of layers or units.

Those of ordinary skill will understand that forming a unit of a circuit board 24 typically includes laminating a conductive sheet to one of the major sides of a non-conductive substrate, or respectively laminating conductive sheets to both of the major sides of the non-conductive substrate. Then, a resist coating may be printed onto the exposed surface of each conductive sheet. Then, the portions of the conductive sheet that are not protected by the resist coating may be chemically etched away, so that the conductive traces are left intact. The non-conductive substrate may comprise glass fibers and epoxy resin, and the conductive sheets and conductive traces may be copper, although any other suitable materials may be used. Alternatively, the conductive traces may be formed in any other suitable manner such as, but not limited to, mechanical milling. Conductive traces and/or other features, such as copper conductive pads, of the circuit board 24 may be connected to one another by way of conductive material extending through (e.g., lining) holes in the non-conductive substrates. The electrical bridge 22 shown in FIG. 1 may be a conductor of the circuit board 24, wherein that conductor of the circuit board may be mounted to a non-conductive substrate of the circuit board. As a more specific example, the electrical bridge 22 may be a conductive trace, conductive pad and/or any other suitable conductive feature(s) of the circuit bard 24.

A prophetic example of how heat may flow within the assembly of FIG. 1 may be understood with reference to FIG. 2, in accordance with the first embodiment. In the example of FIG. 2, the flow of heat from the amplifier 10 to the ambient environment and the flow of heat from the diode 12 to the ambient environment are respectively schematically represented by arrows 26, 28. In accordance with first embodiment and the prophetic example associated with FIG. 2:

1) the heat power generated in the amplifier 10 is 40W;

2) the heat power generated in the diode 12 is 1W;

3) ambient temperature is 60° C.;

4) block 30 schematically represents the thermal resistance between silicon of the amplifier 10 and the main heat sink 14, and this thermal resistance is 0.6° C./W;

5) block 32 schematically represents the thermal resistance between the main heat sink 14 and the ambient, and this thermal resistance is 0.5° C./W;

6) block 34 schematically represents the thermal resistance between the silicon of the diode 12 and the island or secondary heat sink 16, and this thermal resistance is 20° C./W;

7) block 35 schematically represents the thermal resistance between the secondary heat sink 16 and the ambient, and since the area of the secondary heat sink is significantly smaller than the area of the main heat sink 14, the thermal resistance between the secondary heat sink and the ambient is established as 5° C./W;

8) block 36 schematically represents the thermal resistance between the main and secondary heat sinks 14, 16 (e.g., the thermal resistance of the electrical bridge 22), and the thermal resistance between the main and secondary heat sinks 14, 16 is established as 50° C./W;

9) the temperature of the main heat sink 14 can be calculated to be 80° C. by adding the ambient temperature (i.e., 60° C.) to the product obtained by multiplying the thermal power that flows through the main heat sink to the ambient (i.e., 40W) by the thermal resistance between the main heat sink and the ambient (i.e., 0.5° C./W);

10) the temperature of the secondary heat sink 16 can be calculated to be 65.5° C. by adding the ambient temperature (i.e., 60° C.) to the product obtained by multiplying the thermal power that flows through the secondary heat sink to the ambient (i.e., 1W) by the thermal resistance between the secondary heat sink and the ambient (i.e., 5° C./W);

11) the internal temperature of the amplifier 10 can be calculated to be 104° C. by adding the temperature of the main heat sink 14 (i.e., 80° C.) to the product obtained by multiplying the heat power generated in the amplifier 10 (i.e., 40W) by the thermal resistance between silicon of the amplifier 10 and the main heat sink (i.e., 0.6° C./W); and

12) the internal temperature of the diode 12 can be calculated to be 85.5° C. by adding the temperature of the secondary heat sink 16 (i.e., 65.5° C.) to the product obtained by multiplying the heat power generated in the diode (i.e., 1W) by the thermal resistance between the silicon of the diode and the secondary heat sink (i.e., 20° C./W).

In accordance with the first embodiment and in view of the foregoing prophetic example, the thermal resistance between the heat sinks 14, 16 (e.g., the thermal resistance of the electrical bridge 22) may be greater than at least one of, and is typically greater than both of, thermal resistance between the main heat sink 14 and the amplifier 10, and the thermal resistance between the secondary heat sink 16 and the laser diode 12. In accordance with the first embodiment, the thermal resistance between heat sinks 14, 16 (e.g., the thermal resistance of the electrical bridge 22) may be at least a predetermined value, such as least about 20° C./W, at least about 25° C./W, at least about 30° C./W, at least about 35° C./W, at least about 40° C./W, at least about 45° C./W, at least about 55° C./W, or the thermal resistance between heat sinks 14, 16 may range between any of the preceding values provided for thermal resistance between heat sinks 14, 16.

In accordance with the first embodiment, each of the amplifier 10 and the laser diode 12 generate heat while the electronic apparatus of the first embodiment is operating at steady state, wherein the amplifier is configured for generating at least several times more heat than the laser diode while the electronic apparatus of the first embodiment is operating at steady state, the amplifier is configured for generating at least five times more heat than the laser diode while the electronic apparatus of the first embodiment is operating at steady state, the amplifier is configured for generating at least ten times more heat than the laser diode while the electronic apparatus of the first embodiment is operating at steady state, the amplifier is configured for generating at least twenty times more heat than the laser diode while the electronic apparatus of the first embodiment is operating at steady state, the amplifier is configured for generating at least thirty times more heat than the laser diode while the electronic apparatus of the first embodiment is operating at steady state, the amplifier is configured for generating at least about forty times more heat than the laser diode while the electronic apparatus of the first embodiment is operating at steady state, or the relative amounts of heat generated by the amplifier and the laser diode may fall within a range including and/or between any of the amounts indicated above while the electronic apparatus of the first embodiment is operating at steady state.

In accordance with the first embodiment, the electrical resistance between heat sinks 14, 16 (e.g., the electrical resistance of the electrical bridge 22) may less than a predetermined value.

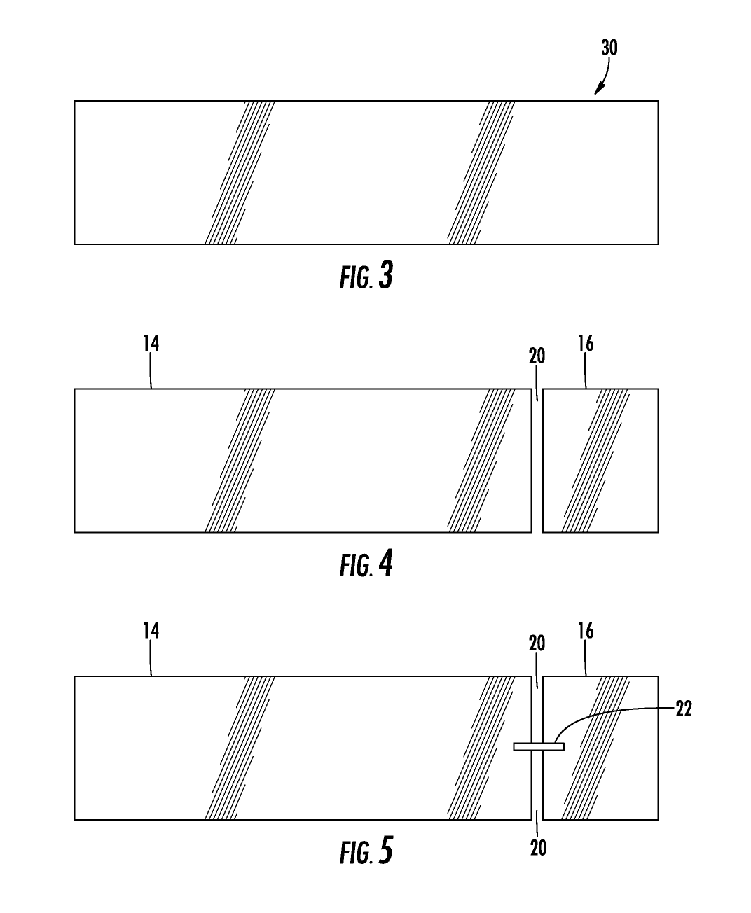

As mentioned above and as one example, the secondary heat sink 16 may be cut out of the main heat sink 14, or cut out of a precursor to the heat sinks. In this regard, an example of a method of at least partially making the electronic apparatus of the first embodiment is discussed in the following. For example, FIG. 3 schematically illustrates a precursor 30 from which the heat sinks 14, 16 may be formed, in accordance with the first embodiment. FIG. 4 schematically illustrates that one or more cuts may be formed in the precursor to form the at least one gap 20 in the precursor, and separate or divide the precursor into the heat sinks 14, 16. The gap 20 may be characterized as extending partially around the secondary heat sink 16, although the gap 20 may be characterized as extending at least partially around the secondary heat sink, and the gap 20 may alternatively extend completely around the secondary heat sink. The gap 20 may be formed in any suitable manner, such as with appropriate conventional cutting tools, and there may be multiple gaps 20 such that more than one of each of (e.g., numerous of each of) the heat sinks 14, 16 may be formed from a single precursor 30.

Alternatively, the heat sinks 14, 16 are not required to be formed from a common precursor 30, and the heat sinks and gap 20 may be in a wide variety of suitable configurations. For example, each of the heat sinks 14, 16 may be formed remotely from one another from a separate precursor, and then there may be relative movement between the heat sinks so that they become proximate to one another and the at least one gap 20 is positioned therebetween.

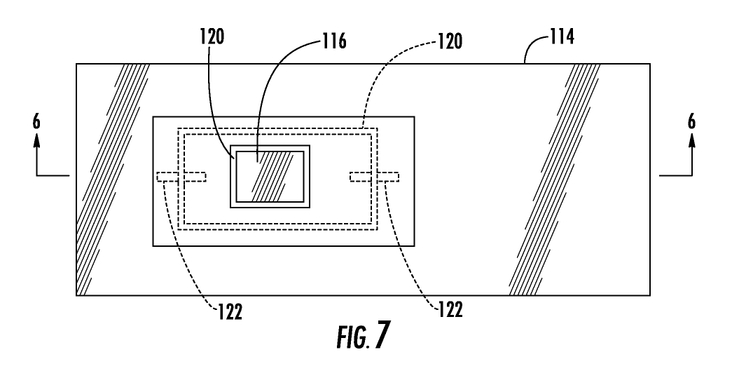

Referring to FIG. 5, one or more electrical bridges 22 may be connected between the heat sinks 14, 16 and span across the gap 20, as discussed above. Also, the amplifier 10 and diode 12 may be respectively connected to the heat skinks 14, 16 as discussed above. Also as at least alluded to above, the heat sinks 14, 16 may at least partially form an enclosure and/or chassis of the electronic apparatus of the first embodiment.

The first embodiment and a second embodiment of this disclosure are alike, except for variations noted and variations what will be apparent to those of ordinary skill in the art. Accordingly, reference numerals for features of the second embodiment that may have at least some similarity to corresponding features of the first embodiment are incremented by 100. As an example of similarities between the first and second embodiments that may be best understood with reference to FIG. 6, the electronic apparatus of the second embodiment may include a main circuit board 124 to which the laser diode 112 is mounted; and an end of the laser diode may be coupled to an end of an optical fiber cable 148 for transmitting optical signals through the cable in response to electrical signals being supplied to the laser diode from the main circuit board. In contrast to the first embodiment, optionally the one or more electrical bridges 122 that bridge the gap(s) 120 between the heat sinks 114, 116 may not be components of the main circuit board 124.

With continued reference to FIG. 6, the laser diode 112 may be substantially thermally isolated from the main heat sink 114 as a result of, for example: the gap(s) 120 between the heat sinks 114, 116; one or more thermally isolating spacers 150 being positioned between the laser diode 112 and the main heat sink 114, wherein each thermally isolating spacer may be constructed of suitable dielectric material; and/or the main circuit board 124 being positioned between the laser diode 112 and the main heat sink 114, wherein any direct engagement between the main circuit board and the main heat sink may be in the form of only nonconductive substrate(s) of the main circuit board engaging the main heat sink.

From a functional standpoint, the electrical bridges 122 may be configured as discussed above for the first embodiment, in a manner that seeks to provided adequate ground plane electrical connectivity. As shown in FIG. 6, the electrical bridges 122 may be positioned on an opposite side of the heat sinks 114, 116 from the main circuit board 124. Alternatively, the electrical bridges 122 may be in any other suitable location. Optionally, the electrical bridges 122 may be parts of at least one secondary printed circuit board 152. In FIG. 6, the secondary circuit board 152 is schematically illustrated by dashed lines as including the electrical bridges 122.

The electrical bridges 122 may be conductors of the secondary circuit board 152, wherein these conductors 122 of the secondary circuit board may be mounted to a non-conductive substrate of the secondary circuit board. As a more specific example, the electrical bridges 122 may be conductive traces, conductive pads and/or any other suitable conductive feature(s) of the one or more secondary circuit board(s) 152. Alternatively, the secondary circuit board 152 may be referred to as a main circuit board or by any other suitable name, and the main circuit board 124 may be referred to as a secondary circuit board or by any other suitable name. Features of the electronic apparatus of the second embodiment may be respectively connected to one another in any suitable manner, such as through the use of fasteners such as, but not limited to, screws 152.

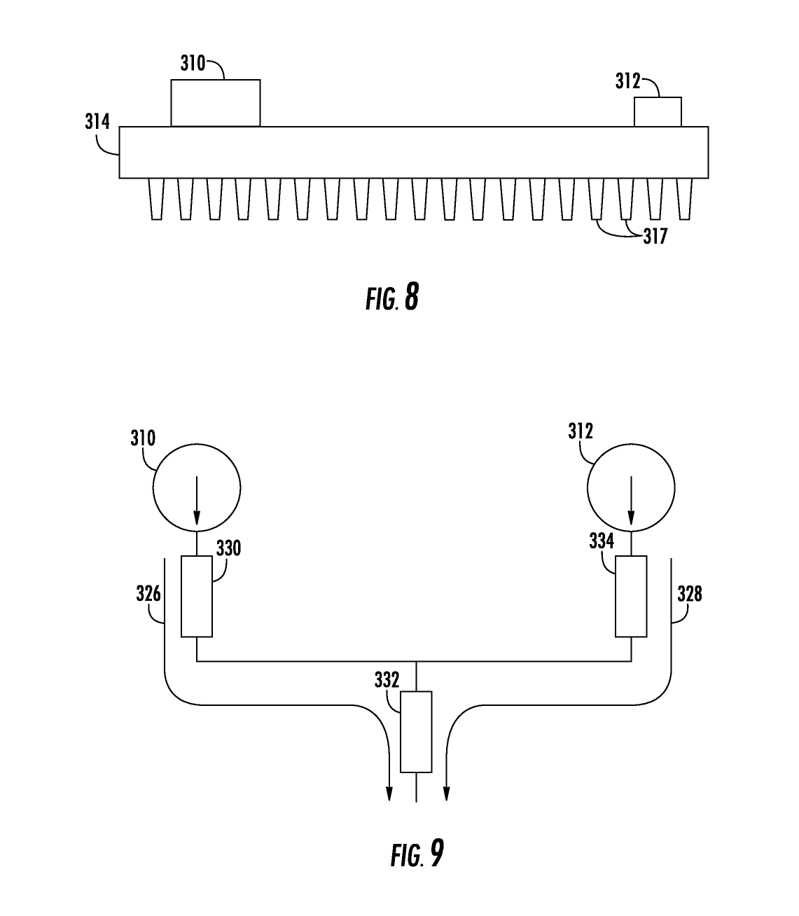

Referring to both the side cross-sectional view of FIG. 6 and top plan view of FIG. 7 (substantially only the heat sinks 114, 116 are shown in FIG. 7), the annular gap 120, which is positioned between the heat sinks, may have numerous sections. For example, in FIG. 7, an annular, upwardly extending lower portion of the gap 120 is hidden from view and shown in dashed lines; and an upwardly extending, annular upper portion of the gap 120 is shown with solid lines. In FIG. 7, the electrical bridges 122 are also hidden from view at the bottom of the heat sinks 114, 116; therefore they are schematically illustrated with dashed lines. Alternatively, the heat sinks 114, 116 may be located at the top of the heat sinks 114, 116 or in any other suitable location.

Referring also to FIG. 6, an annular intermediate portion of the gap 120 extends between the lower portion of the gap 120 and the upper portion of the gap 120 so that the secondary heat sink 116, from the top to the bottom of the secondary heat sink, is completely circumscribed by the compound gap 120. For example, the secondary heat sink may be characterized as being an island heat sink.

If the heat sinks 114, 116 are formed separately from one another rather than being cut from a common precursor, the secondary heat sink 116 may be inserted into a lower end of a hole that extends through the main heat sink 114, so that the compound gap 120 is defined between the heat sinks; the spacer 150 and optionally a portion of the diode 12 and/or a mounting bracket for the diode may extend into an upper portion of the hole in the main heat sink 114; and the main circuit board 124 may extend across and obstruct the upper end of the hole in the main heat sink 114. The features shown in FIGS. 6 and 7 may be configured differently. For example, the features may be oriented in arrangements other than the generally horizontal arrangement shown in FIG. 6, such as by being rotated so that the length of the overall assembly extends vertically or in any other suitable configuration.

A comparative example is discussed with reference to FIGS. 8 and 9, for comparison with aspects of the first embodiment that were discussed above with reference to FIGS. 1 and 2. FIG. 8 illustrates a power amplifier 310 and a laser diode 312 mounted to the same heat sink 314, which includes fins 317. A prophetic, comparative example of how heat may flow within the assembly of FIG. 8 may be understood with reference to FIG. 9. In the comparative example of FIG. 9, the flow of heat from the amplifier 310 to the ambient environment and the flow of heat from the diode 312 to the ambient environment are respectively schematically represented by arrows 326, 328. In the comparative, prophetic example associated with FIG. 5:

1) the heat power generated in the amplifier 310 is 40W;

2) the heat power generated in the diode 312 is 1W;

3) the ambient temperature is 60° C.;

4) block 330 schematically represents the thermal resistance between silicon of the amplifier 310 and the heat sink 314, and this thermal resistance is 0.6° C./W;

5) block 334 schematically represents the thermal resistance between the silicon of the diode 312 and the heat sink 314, and this thermal resistance is 20° C./W;

6) block 332 schematically represents the thermal resistance between the heat sink 314 and the ambient, and this thermal resistance is 0.5° C./W;

7) power that flows through the heat sink 314 to the ambient can be calculated to be 41W by adding the heat power generated in the amplifier 310 (i.e., 40W) and the heat power generated in the diode 312 (i.e., 1W);

8) the temperature of the heat sink 314 can be calculated to be 80.5° C. by adding the ambient temperature (i.e., 60° C.) to the product obtained by multiplying the thermal power that flows through the heat sink 314 to the ambient (i.e., 41W) by the thermal resistance between the heat sink 314 and the ambient (i.e., 0.5° C./W);

9) the internal temperature of the amplifier 310 can be calculated to be 104.5° C. by adding the temperature of the heat sink 314 (i.e., 80.5° C.) to the product obtained by multiplying the power generated in the amplifier 310 (i.e., 40W) by the thermal resistance between silicon of the amplifier 310 and the heat sink 314 (i.e., 0.6° C./W); and

13) the internal temperature of the diode 312 can be calculated to be 100.5° C. by adding the temperature of the heat sink 314 (i.e., 80.5° C.) to the product obtained by multiplying the power generated in the diode (i.e., 1W) by the thermal resistance between the silicon of the diode and the heat sink 314 (i.e., 20° C./W).

In contrast to the internal temperature of the diode 312 (FIG. 8) of the comparative prophetic example being 100.5° C., the internal temperature of the diode 12 (FIG. 2) of the above-discussed prophetic example of the first embodiment is 85° C., which is advantageously lower.

Each of the above-discussed operational examples may be representative of the thermal conditions of the subject electronic apparatus being at, about at and/or substantially at steady state. It is within the scope of this disclosure for the power amplifiers and/or the laser diodes to be replaced with any other suitable electronic device(s).

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

It will be apparent to those skilled in the art that various modifications and variations can be made without departing from the spirit or scope of the invention. Since modifications combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. An electronic apparatus comprising:
first and second electronic devices that each generate heat while the electronic apparatus is operating, the first electronic device being configured for generating at least several times more heat than the second electronic device while the electronic apparatus is operating at steady state;
a first heat sink for dissipating heat, the first heat sink being in communication with the first electronic device, and the communication being comprised of both electrical conductivity between the first electronic device and the first heat sink and thermal conductivity between the first electronic device and the first heat sink, so that the first heat sink is for at least indirectly receiving heat from the first electronic device;
a second heat sink for dissipating heat, the second heat sink being in communication with the second electronic device, and the communication between the second heat sink and the second electronic device being comprised of both electrical conductivity between the second electronic device and the second heat sink, and thermal conductivity between the second electronic device and the second heat sink, so that the second heat sink is for at least indirectly receiving heat from the second electronic device; and
at least one feature between the first and second heat sinks, the at least one feature being configured for simultaneously providing:
electrical conductivity between the first and second heat sinks;
thermal conductivity between the first and second heat sinks; and
thermal resistance between the first and second heat sinks, wherein the thermal resistance between the first and second heat sinks is at least a predetermined value, so that the second heat sink remains cooler than the first heat sink while the electronic apparatus is operating at steady state.

2. The electronic apparatus of claim 1, wherein the at least one feature comprises a gap positioned between the first and second heat sinks.

3. The electronic apparatus of claim 2, wherein the at least one feature comprises at least one electrical bridge connected between the first and second heat sinks and extending across the gap.

4. The electronic apparatus of claim 1, wherein the thermal resistance between the first and second heat sinks is at least about 20° C./W.

5. The electronic apparatus of claim 4, wherein the electrical resistance between the first and second heat sinks is less than a predetermined value.

6. The electronic apparatus of claim 1, wherein:
the first heat sink being in communication with the first electronic device is comprised of the first heat sink and the first electronic device being in direct contact with one another; and
the second heat sink being in communication with the second electronic device is comprised of the second heat sink and the second electronic device being in direct contact with one another.

7. The electronic apparatus of claim 1, wherein:
the first electronic device comprises a power amplifier; and
the second electronic device comprises a laser diode.

8. An electronic apparatus comprising:
a first electronic device and a second electronic device;
a first heat sink for dissipating heat, the first heat sink being in communication with the first electronic device, and the communication being comprised of both electrical conductivity between the first electronic device and the first heat sink, and thermal conductivity between the first electronic device and the first heat sink, so that the first heat sink is for at least indirectly receiving heat from the first electronic device;
a second heat sink for dissipating heat, the second heat sink being in communication with the second electronic device, and the communication between the second heat sink and the second electronic device being comprised of both electrical conductivity between the second electronic device and the second heat sink, and thermal conductivity between the second electronic device and the second heat sink, so that the second heat sink is for at least indirectly receiving heat from the second electronic device; and
the first and second heat sinks being in communication with one another, the communication between the first and second heat sinks being comprised of:
electrical conductivity between the first and second heat sinks, and
thermal conductivity between the first and second heat sinks, wherein the thermal conductivity between the first heat sink and the and second heat sinks is less than at least one thermal conductivity selected from the group consisting of:
the thermal conductivity between the first electronic device and the first heat sink, and
the thermal conductivity between the second electronic device and the second heat sink.

9. The electronic apparatus of claim 8, comprising at least one electrical bridge connected between the first and second heat sinks, wherein
the thermal conductivity between the first and second heat sinks is provided by way of the at least one electrical bridge; and
the electrical conductivity between the first and second heat sinks is provided by way of the at least one electrical bridge.

10. The electronic apparatus of claim 8, wherein thermal conductivity between the first and second heat sinks is less than both the thermal conductivity between the first heat sink and the first electronic device, and the thermal conductivity between the second heat sink and the second electronic device.

11. The electronic apparatus of claim 8, comprising at least one conductor connected to both the first heat sink and second heat sink for providing the communication between the first and second heat sinks, the at least one conductor extending across a gap defined between the first and second heat sinks, and the gap being configured for restricting thermal communication between the first and second heat sinks.

12. The electronic apparatus of claim 8, wherein:
the first heat sink being in communication with the first electronic device is comprised of the first heat sink and the first electronic device being in direct contact with one another; and
the second heat sink being in communication with the second electronic device is comprised of the second heat sink and the second electronic device being in direct contact with one another.

13. The electronic apparatus of claim 8, wherein:
the first electronic device comprises a power amplifier; and
the second electronic device comprises a laser diode.

14. A method for at least partially making an electronic apparatus, the method comprising:
connecting a first electronic device to a first heat sink so that there is both electrical conductivity between the first electronic device and the first heat sink, and thermal conductivity between the first electronic device and the first heat sink;
connecting a second electronic device to a second heat sink so that there is both electrical conductivity between the second electronic device and the second heat sink, and thermal conductivity between the second electronic device and the second heat sink; and
restricting thermal conductivity between the first and second heat sinks without eliminating electrical conductivity between the first and second heat sinks.

15. The method of claim 14, comprising:
providing the electrical conductivity between the first and second heat sinks; and
the providing the electrical conductivity being comprised of connecting at least one electrical bridge between the first and second heat sinks.

16. The method of claim 14, wherein the restricting thermal conductivity is comprised of providing a gap between the first and second heat sinks.

17. The method of claim 16, wherein the providing the gap is comprised of cutting a precursor of the first and second heat sinks.

18. The method of claim 14, wherein:
the restricting thermal conductivity is comprised of forming the first and second heat sinks from a precursor of the first and second heat sinks; and
the forming the first and second heat sinks is comprised of at least partially separating the first and second heat sinks from one another.

19. The method of claim 14, wherein:
the first electronic device comprises a power amplifier; and
the second electronic device comprises a laser diode.
